(19) United States
(12) Patent Application Publication
(10) Pub. No.: US 2025/0102562 A1
(43) Pub. Date: Mar. 27, 2025

(54) MULTI-USER DEVELOPMENT SYSTEM FOR SYSTEM LEVEL DEVICE TESTING

(71) Applicant: Advantest Test Solutions, Inc., San Jose, CA (US)

(72) Inventors: Jess Gillespie, San Jose, CA (US); Amey Subhedar, San Jose, CA (US); Ian Williams, San Jose, CA (US); Karthik Ranganathan, San Jose, CA (US)

(21) Appl. No.: 18/372,369

(22) Filed: Sep. 25, 2023

(51) Int. Cl. G01R 31/28; G01R 31/319

(52) U.S. Cl. CPC G01R 31/2834; G01R 31/31908

(57) ABSTRACT

Embodiments of the present invention provide testing systems that perform advanced system level testing of multiple devices in parallel over a network connection that provides access to multiple development stations for improved efficiency and access to system level testing. A rack integrated computer (RIC) is coupled to multiple tester racks of single board computers (SBCs) and provides access to the SBCs as development workstations for use over a computer network (e.g., a customer network). SBCs can provide end level testing of devices like smartphones that include several different devices (DUTs). Access to the SBCs as development workstations can be enforced on an IP level under a development license, and the license may be used from any global location using a static IP address and/or virtual private network, for example.

### FIELD

Embodiments of the present invention generally relate to the field of electronic device testing. More specifically, embodiments of the present invention relate to system level test systems and methods.

### BACKGROUND

A device or equipment under test (e.g., a DUT) is typically tested to determine the performance and consistency of the electronic device before the device is sold. The device can be tested using a large variety of test cases, and the results of the test cases are compared to expected output results. When the result of a test case does not match the expected output value, the device can be considered a failed device or outlier, or the device can be binned based on performance, etc.

A DUT is usually tested by automatic or automated test equipment (ATE), which may be used to conduct complex testing using software and automation to improve the efficiency of testing. The DUT may be any type of semiconductor device, wafer, or component that is intended to be integrated into a final product, such as a computer system, smartphone, or other electronic device. By removing defective or unsatisfactory chips at manufacture using ATE, the quality of the yield can be significantly improved.

System level testing (SLT) advances conventional approaches to DUT testing that may test only a specific processor, memory device, material, or the like, by testing multiple system components that are connected and configured in a way that is similar to an end product. In system level testing, the socket includes the support hardware necessary to test key functions of an application processor, for example, at a system level. Modern system level testers are complicated and expensive, and current approaches to system level testing typically require a special production license. Therefore, most entities have access to a relatively small number of system level test systems for testing application processors and the like. Accordingly, a more efficient and accessible approach to system level testing is desired.

### SUMMARY

Embodiments of the present invention provide testing systems that perform advanced system level testing of multiple devices in parallel over a network connection that provides access to multiple development stations for improved efficiency and access to system level testing. A rack integrated computer (RIC) is coupled to multiple tester racks of single board computers (SBCs) and provides access to the SBCs as development workstations for use over a computer network (e.g., a customer network). SBCs can provide end level testing of devices like smartphones that include several different devices (DUTs). Access to the SBCs as development workstations can be enforced on an IP level under a development license, and the license may be used from any global location using a static IP address assigned to an SBC over a VPN, for example.

According to one disclosed embodiment, a system level test system is disclosed including a rack integrated computer coupled to a network switch to provide a remote network connection to a plurality of single board computers, and the network switch is coupled to the plurality of SBCs. The plurality of SBCs are operable to perform system level testing on a plurality of devices under test, and the plurality of SBCs are operable to be coupled to the plurality of DUTs. The system level testing includes testing a plurality of components of the plurality of DUTs according to a test program executed by the plurality of SBCs over the remote network connection.

According to some embodiments, the system level test system includes a tester rack, with the RIC disposed in the tester rack, a power distribution board disposed in a slot of the tester rack and coupled to the plurality of SBCs, and a test interface board disposed in the slot of the tester rack and operable to be coupled to the plurality of DUTs.

According to some embodiments, the system level test system includes a lookup table stored in a memory of the RIC. The lookup table includes a designated IP address for accessing a first SBC of the plurality of SBCs, and the first SBC is configured using the IP address. The first SBC is operable to be remotely accessed using the IP address to perform the system level testing.

According to some embodiments, the first SBC is accessed using a license file that enables a development mode that allows connection to the first SBC from any IP address.

According to some embodiments, the network switch includes an ethernet switch.

According to some embodiments, the plurality of SBCs include 6 SBCs, and the plurality of DUTs include 24 DUTs, with each SBC of the plurality of SBCs respectively coupled to 4 DUTs of the plurality of DUTs for performing the system level testing via the remote network connection.

According to some embodiments, the remote network connection provides communication between the plurality of SBCs and a remote computer system using at least one of VNC, Remote Desktop Connection, and an integrated development environment.

According to some embodiments, the plurality of SBCs are operable to install a custom IDE via the remote network connection.

According to some embodiments, the plurality of SBCs are operable to install a custom software library via the remote network connection.

According to some embodiments, the system level test system includes a plurality of network switches coupled to a plurality of tester racks, and each tester rack includes another plurality of SBCs operable to be coupled to another plurality of DUTs. The plurality of network switches is coupled to the RIC to coordinate remote access to the another plurality of SBCs for performing the system level testing on the another plurality of DUTs.

According to another embodiment, a single board computer for performing system level testing is disclosed. The SBC includes a processor, a memory, and a network interface. The processor is operable to perform system level testing on a plurality of DUTs operable to be coupled to the processor, and the network interface is coupled to a network switch. The network switch is coupled to a rack integrated computer (RIC) that coordinates remote access between the networking interface and a remote computer system.

According to some embodiments, the plurality of DUTs are operable to be coupled to the processor using a USB interface.

According to some embodiments, the plurality of DUTs includes 4 DUTs, and the processor is operable to perform the system level testing on the 4 DUTs in parallel.

According to some embodiments, the processor is operable to assign a designated IP address to the network interface for connecting to the remote network, and the designated IP address is stored in a lookup table in a memory of the RIC.

According to some embodiments, the network switch includes an ethernet switch.

According to another embodiment, a method of system level testing is disclosed. The method includes associating a single board computer (SBC) with a designated IP address, storing the designated IP address in a lookup table in a memory of a rack integrated computer. The RIC and the SBC are coupled to a network switch, and the SBC is accessible by a remote computer system at the designated IP address via the RIC. The remote computer system causes the SBC to perform system level testing on a plurality of devices under test operable to be coupled to the SBC.

According to some embodiments, the plurality of DUTs include 4 DUTs, and the SBC is operable to perform the system level testing on the 4 DUTs in parallel.

According to some embodiments, the system level testing includes the SBC receiving test commands and data from the remote computer system, and the SBC returning test results to the remote computer system.

According to some embodiments, the SBC executes an integrated development environment controlled by the remote computer system.

According to some embodiments, the SBC is further accessible via the IP address in combination with a port number according to the port forwarding rules defined in the lookup table.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 depicts exemplary single board computers for testing multiple DUTs in parallel according to embodiments of the present invention.

FIG. 2 depicts an exemplary system level test system for testing 4 DUTs in parallel using a single SBC according to embodiments of the present invention.

FIG. 3 depicts an exemplary system level test system including tester racks that execute SLT test environments that are remotely accessible by a customer network according to embodiments of the present invention.

FIG. 4 depicts an exemplary computer network for performing SLT according to embodiments of the present invention.

FIG. 5 depicts an exemplary sequence of computer implemented steps for performing system level testing remotely according to embodiments of the present invention.

FIG. 6 depicts an exemplary computer platform upon which embodiments of the present invention may be implemented.

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

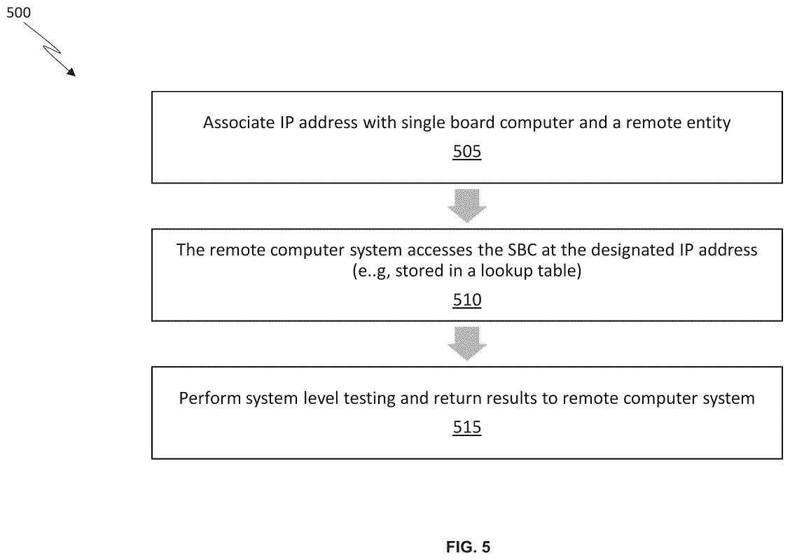

Some portions of the detailed description are presented in terms of procedures, steps, logic blocks, processing, and other symbolic representations of operations on data bits that can be performed on computer memory (e.g., FIG. 5). These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, parameters, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “associating,” “identifying,” “encoding,” “labeling,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some embodiments may be described in the general context of computer-executable instructions, such as program modules, executed by one or more computers or other devices. Generally, program modules include routines, algorithms, programs, objects, components, data structures, etc. that perform particular tasks or implement particular abstract data types. Typically, the functionality of the program modules may be combined or distributed as desired in various embodiments.

### Multi-User Development System for System Level Testing Via Remote Access

Embodiments of the present invention provide testing systems that perform advanced system level testing of multiple devices in parallel over a network connection that provides access to multiple development stations for improved efficiency and access to system level testing. A rack integrated computer (RIC) is coupled to multiple tester racks of single board computers (SBCs) and provides access to the SBCs as development workstations for use over a computer network (e.g., a customer network). SBCs can provide end level testing of devices like smartphones that include several different devices (DUTs). Access to the SBCs as development workstations can be enforced on an IP level under a development license, and the license may be used from any global location using a static IP address and/or virtual private network, for example.

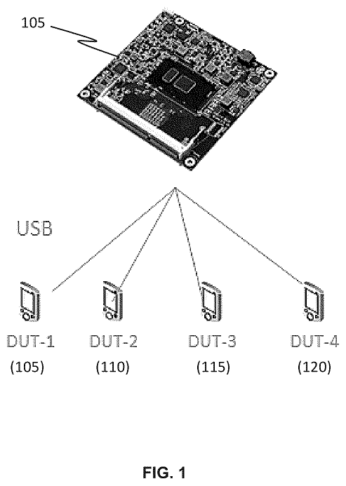

FIG. 1 depicts exemplary single board computers (SBCs) for testing multiple DUTs in parallel according to embodiments of the present invention. In the example of FIG. 1, SBC 105 is coupled to DUT-1 (110), DUT-2 (115), DUT-3 (120), and DUT-4 (125) over a USB connection. SBC 105 provides end level testing of devices that include several different devices (DUTs), such as smartphones and other modern electronic devices. SBCs are typically controlled by active control software that coordinate testing efforts and act as an interface between the active control software and the DUTs by sending commands to the DUTs and returning results to the active control software. However, embodiments of the present invention can bypass the active control software and use each SBC as an independent development workstation that connects to the customer hardware in the actual test environment.

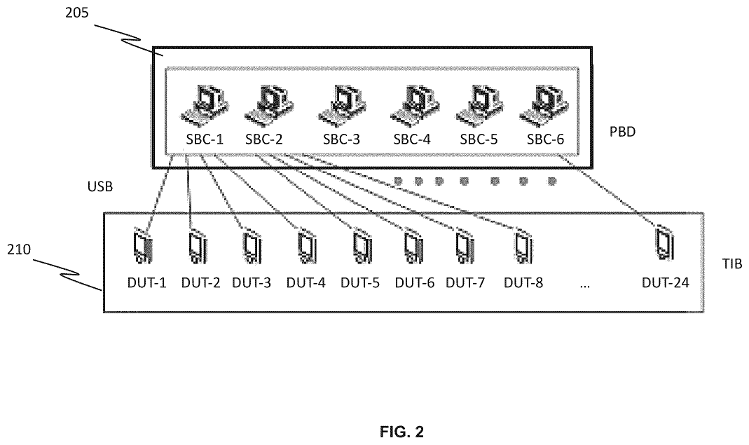

As depicted in FIG. 2, each slot of a powder distribution board (BPD) can include multiple SBCs connected to up to 4 DUTs for system level testing according to embodiments of the present invention. In the embodiment of FIG. 2, up to 4 DUTs can be tested in parallel by a single SBC, and up to 24 DUTs can be tested per slot. The SCBs 205 can be connected to the DUTs 210 over USB, for example, to test the DUTs 210 at a system level. The system level testing can be performed over a network connection, and access to the SCBs can be enforced according to licensing based on IP address, for example.

A RIC can act as a system controller to coordinate the system level testing by controlling the handler, logging system level test results, etc. Typically, the SBCs 205 are placed in a power distribution board, and the DUTs are placed in a test interface board, which reside in a slot of a tester rack. The PBDs and the TIBs can be installed and uninstalled by a handler controlled by the RIC, for example.

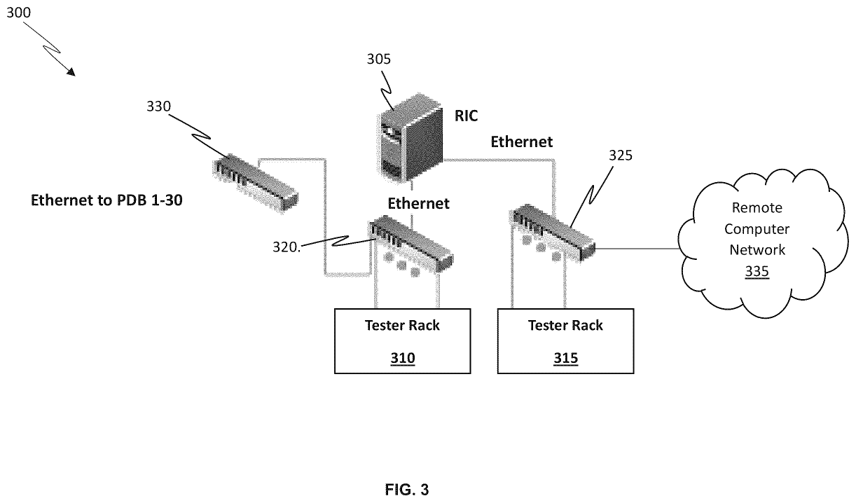

FIG. 3 depicts an exemplary system level test system 300 including tester rack 310 and tester rack 315 executing SLT test environments configured for remotely access by a customer network 335 according to embodiments of the present invention.

Rack integrated computer system (RIC) 305 provides access to tester rack 310 and tester rack 315 for system level testing via remote access using ethernet switches 320 and 325, respectively. In this way, remote entities can test a large number of devices (e.g., smartphones and other digital electronic devices) at a system level via remote access, and can execute test software using the SBCs to test multiple DUTs of a device, including application processors, memory, and the like. After system level testing of the DUTs is completed, RIC 305 can automatically remove the DUTs and replace them with new DUTs to be tested.

The SBCs disposed in 310 and rack 315 can be configured to act as remote development stations that are accessible remotely via commands that are transmitted over a network, such as VNC, Remote Desktop Connection (RDC), or by specialized development software such as Eclipse or other integrated development environments (IDEs). Alternatively, an IDE already built into the SBCs may be used, such as ActiveATE. Any suitable development libraries such as Python, Java, and C#can be installed, along with any license files used for remote development. During testing, the SBCs act as supervisory processors and handle communication between the remote computer network 335 and the DUTs disposed in the TIBs of rack 310 and rack 315 to coordinate system level testing.

According to some embodiments, SBC Development mode is enabled by providing a valid license file, which allows remote connections from any designated IP address to develop and/or execute system level test programs. Moreover, a smart hub can be configured using port forwarding to provide access to multiple SBCs for testing using a static IP address and port numbers according to routing rules defined for various port numbers. According to some embedment, IP address 192.168.0.1 is assigned to the RIC 305, and only the RIC can access the SBCs when development mode is not enabled.

According to some embodiments, access to the SBCs for system level DUT testing is controlled at an IP level using dedicated static IP address as defined in a lookup table. In this way, specific IP addresses can be assigned to SBCs for access by remote entities for remote development of SLT testing. The SBCs can automatically set their own IP addresses to control remote access store the IP addresses in the lookup table. Specific licenses can be assigned to entities for remote development, and a license file can be used to access the SLT system to enable a development mode that allows access to additional IP addresses.

According to some embodiments, the SBCs are accessed for system level DUT testing over a virtual private network (VPN) at the designated IP address, and port forwarding may be used to map specific ports to different entities or development environments, for example. The SBCs can be configured with custom development tools to enable a user to control a group of up to 4 test devices as a “test site”. Multiple test sites can be accessed by a designated entity to test more devices in parallel, or to test different types of devices, for example.

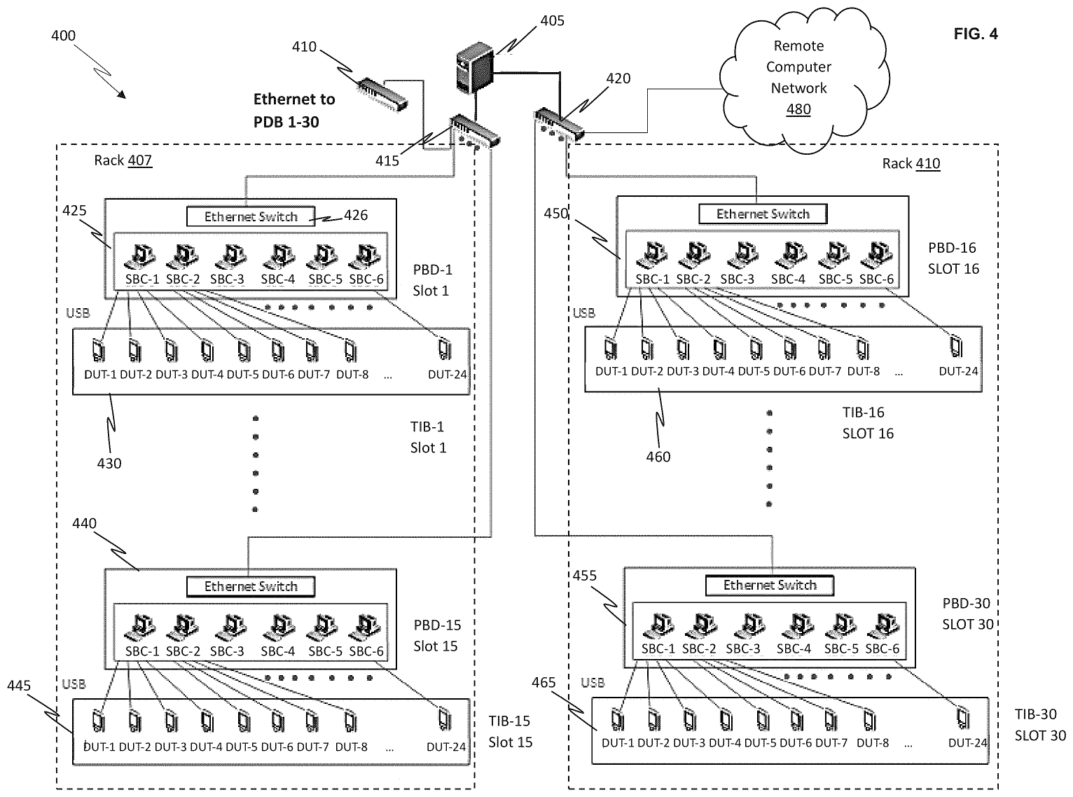

FIG. 4 depicts an exemplary computer network 400 for performing SLT according to embodiments of the present invention. Computer network 400 includes an RIC 405 coupled to ethernet switches 410, 415, and 420 for coordinating SLT testing using racks of SBCs over a network connection by a remote computer system 480. Ethernet switch 415 provides Ethernet access to the PBDs of racks 407, 410. As mentioned above, each SBC can be configured as an independent development workstation that connects to the hardware in the actual test environment. In this way, each SBC can perform system level testing on up to 4 DUTs in parallel from any global location via remote access.

Typically, the test racks include power distribution boards (PDBs) for accommodating SBCs, and test interface boards (TIBs) for accommodating multiple DUTs. In the example of FIG. 4, tester rack 407 includes 6 SBCs disposed on PBD 425 of slot 1, and each SBC is coupled to 4 DUTs disposed on the TIB 430 of slot 1 for system level testing. Rack 407 includes PDBs and TIBs disposed in slots 1-15 (e.g., PBDs 425, 440 and TIBs 430, 445), with each PDB being connected to ethernet switch 415. Similarly, the PBDs of rack 410 PBD 4 are coupled to ethernet switch 420, and rack 2 includes slots 16-30 for accommodating PBDs and TIBs (e.g., PBDs 450, 455 and TIBs 460, 465) to test DUTs at a system level using SBCs. The. In the example of FIG. 4, racks 407, 410 include 15 slots each for a total of 720 connected DUTs.

Each PDB also includes an ethernet switch or interface that connects the PBD to one of the ethernet switches connected to RIC 405. RIC 405 coordinates network communication between remote computer network 480 and the SBCs via network switches 415 and 420. In the example of FIG. 4, PBD 425 disposed in slot 1 includes ethernet switch 426 coupled to ethernet switch 415 to provide communication between the SBCs and RIC 405. The SBCs coupled to ethernet switch 435 can be accessed by customer computer network 480 via remote access to perform system level testing on the DUTs, which increases the availability of SLT systems and improves testing efficiency for testing multiple DUTs in parallel.

FIG. 5 depicts an exemplary sequence of computer implemented steps for performing system level testing remotely according to embodiments of the present invention.

At step 505, a designated IP address is assigned to a single board computer disposed in a tester rack and associated with a remote entity, computer system, or computer network. The designated IP address can be stored in a lookup table of the rack integrated computer or on the single board computer, for example. The rack integrated computer is coupled to ethernet switches for communicating with the single board computers to perform SLT operations via remote access. Typically, the SBCs are disposed in a PDB placed in a tester rack, and the DUTs to be tested by the SBCs are disposed in a TIB installed in the same slot of the tester rack.

At step 510, the remote entity accesses the single board computer at the designated IP address. The remote entity can access the single board computer via remote access using VNC, Remote Desktop Connection, or an IDE, for example. Moreover, a VPN can be used to access the designated IP address using port forwarding, according to embodiments.

At step 515, system level testing is performed by the SBCs to test the DUTs disposed in the TIB. The system level testing is coordinated by the RIC which acts as a supervisory processor. An IDE is used as a development platform by the remote entity and the SBCs execute test commands/instructions according to code developed using the IDE. Step 515 can include remote system level testing of multiple DUTs in parallel, and can further include executing test code using multiple SBCs to test a larger number of DUTs, to test DUTs using different IDEs, different test code, etc. The SBCs can act as a middleman between the DUTs and the IDEs by passing test data and commands to the DUTs and returning results of SLT test operations over the computer network to the remote computer system. In this way, system level testing is made available to computer systems located anywhere in the world, and remote entities can perform SLT operations as if they have physical access to the testing equipment.

### Exemplary Test System

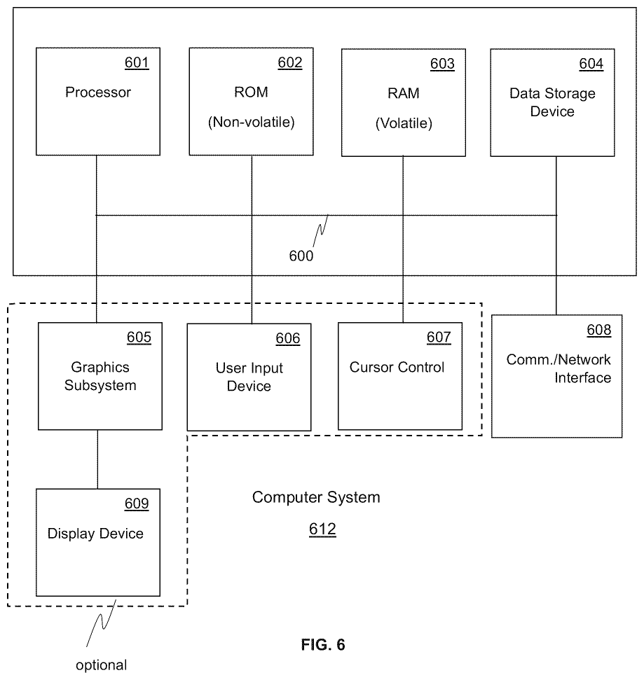

Embodiments of the present invention are drawn to electronic systems for performing system level testing that is accessible to a remove network of computer systems. The embodiment depicted in FIG. 6 can be a single board computer or a rack integrated computer (RIC), for example, which are discussed above. Further, system 612 can be used to execute process 500 shown in in FIG. 5.

In the example of FIG. 6, the exemplary computer system 612 can be configured as a server and includes a central processing unit (CPU) 601 for running software applications and an operating system. Random access memory 602 and read-only memory 603 store applications and data for use by the CPU 601. Data storage device 604 provides non-volatile storage for applications and data and may include fixed disk drives, removable disk drives, flash memory devices, and CD-ROM, DVD-ROM or other optical storage devices. The data storage device 604 or the memory 602/603 can store historic and real-time testing data (e.g., test results, limits, computations, etc.). The optional user inputs 606 and 607 comprise devices that communicate inputs from one or more users to the computer system 612 (e.g., mice, joysticks, cameras, touch screens, keyboards, and/or microphones). A communication or network interface 608 allows the computer system 612 to communicate with other computer systems, networks, or devices via an electronic communications network, including wired and/or wireless communication and including an Intranet or the Internet. Communication or network interface 608 can be coupled to or can include an ethernet switch, according to embodiments, and can be assigned a static designated IP address.

The optional display device 610 may be any device capable of displaying visual information in response to a signal from the computer system 612 and may include a flat panel touch sensitive display, for example. The components of the computer system 612, including the CPU 601, memory 602/603, data storage 604, user input devices 606, and graphics subsystem 605 may be coupled via one or more data buses 600. In the case of a single board computer, graphics subsystem is integrated into the processor 601.

Embodiments of the present invention are thus described. While the present invention has been described in particular embodiments, it should be appreciated that the present invention should not be construed as limited by such embodiments, but rather construed according to the following claims.

What is claimed is:

1. A system level test system, comprising:
a rack integrated computer (RIC) coupled to a network switch to provide a remote network connection to a plurality of single board computers (SBCs); and
the network switch coupled to the plurality of SBCs, wherein the plurality of SBCs are operable to perform system level testing on a plurality of devices under test (DUTs), wherein the plurality of SBCs are operable to be coupled to the plurality of DUTs, and wherein the system level testing comprises testing a plurality of components of the plurality of DUTs according to a test program executed by the plurality of SBCs over the remote network connection.

2. The system level test system of claim 1, further comprising:
a tester rack, wherein the RIC is disposed in the tester rack;
a power distribution board (PBD) disposed in a slot of the tester rack and coupled to the plurality of SBCs; and
a test interface board (TIB) disposed in the slot of the tester rack and operable to be coupled to the plurality of DUTs.

3. The system level test system of claim 1, further comprising a lookup table stored in a memory of the RIC, wherein the lookup table comprises a designated IP address for accessing a first SBC of the plurality of SBCs, wherein further the first SBC is configured using the IP address, and wherein the first SBC is operable to be remotely accessed using the IP address to perform the system level testing.

4. The system level test system of claim 3, wherein the first SBC is accessed using a license file that enables a development mode that allows connection to the first SBC from any IP address.

5. The test system of claim 1, wherein the network switch comprises an ethernet switch.

6. The test system of claim 1, wherein the plurality of SBCs comprise 6 SBCs, and wherein the plurality of DUTs comprise 24 DUTs, and wherein each SBC of the plurality of SBCs is respectively coupled to 4 DUTs of the plurality of DUTs for performing the system level testing via the remote network connection.

7. The test system of claim 1, wherein the remote network connection provides communication between the plurality of SBCs and a remote computer system using at least one of: VNC; Remote Desktop Connection; and an integrated development environment (IDE).

8. The test system of claim 1, wherein the plurality of SBCs are operable to install a custom IDE via the remote network connection.

9. The test system of claim 1, wherein the plurality of SBCs are operable to install a custom software library via the remote network connection.

10. The test system of claim 1, further comprising a plurality of network switches coupled to a plurality of tester racks, wherein each tester rack comprises another plurality of SBCs operable to be coupled to another plurality of DUTs, and wherein the plurality of network switches are coupled to the RIC to coordinate remote access to the another plurality of SBCs for performing the system level testing on the another plurality of DUTs.

11. A single board computer (SBC) for performing system level testing, the SBC comprising:
a processor;
a memory; and
a network interface,
wherein the processor is operable to perform system level testing on a plurality of DUTs operable to be coupled to the processor, wherein the network interface is coupled to a network switch, and wherein the network switch is coupled to a rack integrated computer (RIC) that coordinates remote access between the networking interface and a remote computer system.

12. The SBC of claim 11, wherein the plurality of DUTs are operable to be coupled to the processor using a USB interface.

13. The SBC of claim 11, wherein the plurality of DUTs comprise 4 DUTs, and wherein the processor is operable to perform the system level testing on the 4 DUTs in parallel.

14. The SBC of claim 11, wherein the processor is operable to assign a designated IP address to the network interface for connecting to the remote network, and wherein the designated IP address is stored in a lookup table in a memory of the RIC.

15. The SBC of claim 11, wherein the network switch comprises an ethernet switch.

16. A method of system level testing, comprising:
associating a single board computer (SBC) with a designated IP address;
storing the designated IP address in a lookup table in a memory of a rack integrated computer (RIC), wherein RIC and the SBC are coupled to a network switch, and wherein further the SBC is accessible by a remote computer system at the designated IP address via the RIC; and
the remote computer system causing the SBC to perform system level testing on a plurality of devices under test (DUTs) operable to be coupled to the SBC.

17. The method of claim 16, wherein the plurality of DUTs comprise 4 DUTs, and wherein the SBC is operable to perform the system level testing on the 4 DUTs in parallel.

18. The method of claim 16, wherein the system level testing comprises:
the SBC receiving test commands and data from the remote computer system; and
the SBC returning test results to the remote computer system.

19. The method of claim 16, wherein the SBC executes an integrated development environment (IDE) controlled by the remote computer system.

20. The method of claim 16, further comprising storing port forwarding rules at the RIC in the lookup table, wherein the SBC is further accessible via the IP address in combination with a port number according to the port forwarding rules defined in the lookup table.
